(19) United States
(12) Patent Application Publication
(10) Pub. No.: US 2006/0214206 A1
(43) Pub. Date: Sep. 28, 2006

(54) Ferroelectric memory device and method of manufacturing the same

(76) Inventor: Susumu Shuto, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/377,166

(22) Filed: Mar. 17, 2006

(30) Foreign Application Priority Data
Mar. 24, 2005 (JP) 2005-085988

(51) Int. Cl. H01L 29/94

(52) U.S. Cl. 257/295

(57) ABSTRACT

There is disclosed a ferroelectric memory device comprising an MIS transistor formed on a substrate, a ferroelectric film which is formed above the MIS transistor through an interlayer insulating film, and which has a width substantially equal to a channel length of the MIS transistor, and a same wiring layer which connects a diffusion layer of the MIS transistor formed in a surface region of the substrate to a side surface of the ferroelectric film.

### CROSS-REFERENCE TO RELATED APPLICATIONS

This application is based upon and claims the benefit of priority from prior Japanese Patent Application No. 2005-085988, filed Mar. 24, 2005, the entire contents of which are incorporated herein by reference.

### BACKGROUND OF THE INVENTION

1. Field of the Invention

The present invention relates to a ferroelectric memory device and a method of manufacturing the same.

2. Description of the Related Art

Ferroelectric memory devices are drawing attention as nonvolatile memories featuring high-speed operation and low-power consumption, and the application thereof to IC cards, FeRAM mixed microcomputers, and the like has been mainly under review. In order to broaden the application, a ferroelectric memory device having a higher capacity is required. A reduction in a cell area is fundamental to making a device have a high capacity. For that purpose, an improvement of a cell circuit system and an improvement of a cell capacitor structure have been carried out.

As an improvement of a cell circuit system, a transition from a conventional 2-transistor/2-capacitor (2T2C) structure to a 1-transistor/1-capacitor (1T1C) structure has been carried out. As another improvement of the cell circuit system, an improvement with respect to a chain type ferroelectric memory device in which a plurality of cells are connected in series and share one bit line, has been carried out.

On the other hand, in order to broaden a capacitor area, changes from a flat type (planer type) capacitor structure to a stacked capacitor-on-plug (COP type) structure, and further, to a structure in which the source/drain electrodes extend on the side surfaces of a ferroelectric layer have been under review as improvements of a cell capacitor structure. In order to further reduce a cell area, an improvement to a structure called a vertical capacitor structure, in which a direction connecting the both electrodes of a ferroelectric capacitor goes along a channel direction of a transistor has been under review (for example, refer to Jpn. Pat. Appln. KOKAI Publication No. 2002-289797). As shown in FIG. 7 of Jpn. Pat. Appln. KOKAI Publication No. 2002-289797, the vertical capacitor structure requires extra space for preventing misalignment between a contact hole 8 provided at a transistor on a semiconductor substrate and a capacitor electrode 14 (1) provided at the upper portion of the contact hole 8 is required, which has made reduction of cell size difficult.

### BRIEF SUMMARY OF THE INVENTION

According to an aspect of the present invention, there is provided a ferroelectric memory device comprising:

an MIS transistor formed on a substrate;

a ferroelectric film which is formed above the MIS transistor through an interlayer insulating film, and which has a width substantially equal to a channel length of the MIS transistor; and

a same wiring layer which connects a diffusion layer of the MIS transistor formed in a surface region of the substrate to a side surface of the ferroelectric film.

According to another aspect of the present invention, there is provided a ferroelectric memory device comprising:

an MIS transistor formed on a substrate;

a ferroelectric film which is formed above the MIS transistor through an interlayer insulating film, and which has a width shorter than a channel length of the MIS transistor;

a wiring film of a predetermined thickness formed on a side surface of the ferroelectric film; and

a wiring layer which is embedded between two cells adjacent to each other, and which connects a diffusion layer of the MIS transistor formed in a surface region of the substrate to the ferroelectric film through the wiring film.

According to a further aspect of the present invention, there is provided a ferroelectric memory device comprising:

an MIS transistor formed on a substrate;

a ferroelectric capacitor which is formed from a ferroelectric film and a pair of electrodes through an interlayer insulating film above the MIS transistor, the pair of electrodes being arranged in a direction of a channel length of the MIS transistor; and

a same wiring layer which connects a diffusion layer of the MIS transistor formed in a surface region of the substrate to a corresponding one of the electrodes of the ferroelectric capacitor.

According to a further aspect of the present invention, there is provided a ferroelectric memory device comprising:

an MIS transistor formed on a substrate;

a ferroelectric capacitor which is formed from a ferroelectric film and a pair of electrodes through an interlayer insulating film above the MIS transistor, the pair of electrodes being arranged in a direction of a channel length of the MIS transistor;

a wiring film of a predetermined thickness formed on a side surface of the ferroelectric film; and

a wiring layer which is embedded between two cells adjacent to each other, and which connects a diffusion layer of the MIS transistor formed in a surface region of the substrate to the ferroelectric film through the wiring film.

According to a further aspect of the present invention, there is provided a method of manufacturing a ferroelectric memory device, comprising:

forming an insulating film on a surface of a substrate;

depositing a gate electrode film on the insulating film;

depositing an interlayer insulating film on the gate electrode;

depositing a ferroelectric film on the interlayer insulating film;

processing the ferroelectric film, the interlayer insulating film, the gate electrode film, and the insulating film mutually in a self-aligning manner;

forming diffusion layers in the substrate; and

forming a same wiring film which connects the ferroelectric film and the diffusion layers.

According to a further aspect of the present invention, there is provided a method of manufacturing a ferroelectric memory device, comprising:

forming an insulating film on a principal surface of a substrate;

depositing a gate electrode film on the insulating film;

depositing an interlayer insulating film on the gate electrode;

depositing a ferroelectric film on the interlayer insulating film;

processing the ferroelectric film;

forming capacitor electrode films on side surfaces of the processed ferroelectric film;

processing the interlayer insulating film, the gate electrode film, and the insulating film mutually with the capacitor electrode films in a self-aligning manner;

forming diffusion layers in the substrate; and

forming a buried wiring layer which connects the ferroelectric film and the diffusion layers.

### BRIEF DESCRIPTION OF THE SEVERAL VIEWS OF THE DRAWING

FIG. 1 is a cross-sectional view of a ferroelectric memory device according to a first embodiment of the present invention;

FIG. 2 is a cross-sectional view of a device structure in one manufacturing process of a method of manufacturing the ferroelectric memory device according to the first embodiment of the invention;

FIG. 3 is a cross-sectional view of the device structure in a manufacturing process following the manufacturing process shown in FIG. 2, of the method of manufacturing the ferroelectric memory device according to the first embodiment of the invention;

FIG. 4 is a cross-sectional view of the device structure in a manufacturing process following the manufacturing process shown in FIG. 3, of the method of manufacturing the ferroelectric memory device according to the first embodiment of the invention;

FIG. 5 is a cross-sectional view of the device structure in a manufacturing process following the manufacturing process shown in FIG. 4, of the method of manufacturing the ferroelectric memory device according to the first embodiment of the invention;

FIG. 6 is a cross-sectional view of the device structure in a manufacturing process following the manufacturing process shown in FIG. 5, of the method of manufacturing the ferroelectric memory device according to the first embodiment of the invention;

FIG. 7 is a cross-sectional view of the device structure in a manufacturing process following the manufacturing process shown in FIG. 6, of the method of manufacturing the ferroelectric memory device according to the first embodiment of the invention;

FIG. 8 is a plan view of a ferroelectric memory device according to a second embodiment of the present invention;

FIG. 9 is a cross-sectional view of the ferroelectric memory device taken along the line IX-IX of FIG. 8;

FIG. 10 is a cross-sectional view of the ferroelectric memory device taken along the line X-X of FIG. 8;

FIG. 11 is a plan view of a ferroelectric memory device according to a third embodiment of the present invention;

FIG. 12 is a cross-sectional view of the ferroelectric memory device taken along the line XI-XI of FIG. 11;

FIG. 13 is a cross-sectional view of the ferroelectric memory device taken along the line XII-XII of FIG. 11;

FIG. 14 is a cross-sectional view of a device structure in one manufacturing process of a method of manufacturing a semiconductor device according to the third embodiment of the invention; and

FIG. 15 is a cross-sectional view of the device structure in a manufacturing process following the manufacturing process shown in FIG. 14, of the method of manufacturing the semiconductor device according to the third embodiment of the invention.

### DETAILED DESCRIPTION OF THE INVENTION

### First Embodiment

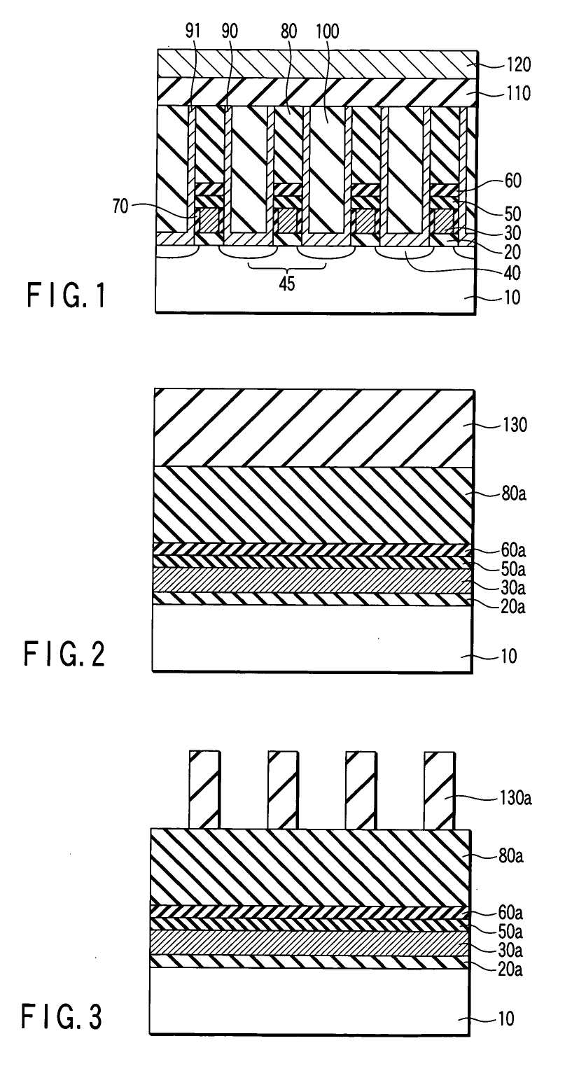

FIG. 1 is a cross-sectional view, in a direction of a bit line, of a ferroelectric memory device according to a first embodiment of the present invention.

A gate insulating film 20 composed of, for example, a silicon oxide film or a nitrogen-added silicon oxide film is formed on a silicon substrate 10, and a gate electrode 30 composed of, for example, polycrystalline silicon doped with impurities is formed on the gate insulating film 20. Source/drain layers 40 composed of impurity diffusion layers 40 are formed within a surface region of the substrate 10 at the both sides of the gate electrode 30. A metal insulator semiconductor (MIS) transistor 45 is comprised of the gate insulating film 20, the gate electrode 30, and the source/drain layers 40.

Sidewall insulating films 70 are formed on the side surfaces of the gate electrode, and the side surfaces of the gate electrode are isolated from the periphery by the sidewall insulating films 70.

On the gate electrode 30, a first interlayer insulating film 50 composed of a silicon nitride film, a silicon oxide film, a nitrogen-added silicon oxide film, or the like, and a second interlayer insulating film 60 composed of alumina or the like are successively deposited. A ferroelectric film 80 made of, for example, PZT (Pb (ZrₓTi₁₋ₓO₃)) is provided on the gate electrode 30 through the first interlayer insulating film 50 and the second interlayer insulating film 60. A material of the ferroelectric film 80 may be not necessarily PZT (Pb (ZrₓTi₁₋ₓO₃)). For example, it may be SBT (SrBi₂Ta₂O₉) or BLT ((BiLa)₄Ti₃O₁₂), and further, may be a ferroelectric material that elements such as Sr, Ba, Ca, La, Nb, W, Mg, Co, Fe, Ni, and Mn are added to those materials.

Electrodes 90 and 91 are formed so as to face each other in a direction of the channel length of the transistor at the both sides of the ferroelectric film 80. The ferroelectric capacitor is formed from the ferroelectric film 80 and the electrodes 90 and 91. Examples of the material of the electrodes 90 and 91 include Pt, RuO₂, and IrO₂. The transistor and the ferroelectric film 80 are arranged in a self-aligning manner, and the cannel length of the transistor and a distance between the two electrodes 90 and 91 of the ferroelectric capacitor are substantially equal to each other. “Substantially equal” means that a difference between the channel length and the distance between the electrodes falls within an error brought about at the time of processing.

The electrodes 90 and 91 are respectively connected to the diffusion layers 40 of the transistor via wiring layers.

A space among elements adjacent to one another is filled with a third interlayer insulating film 100 composed of, for example, SiO₂, BPSG, BSG, PSG, or a fluoridated film thereof.

A structure composed of one transistor 45 and one ferroelectric capacitor including the ferroelectric film 80 and the electrodes 90 and 91 at the both sides of the ferroelectric film 80 is defined as a cell, and a structure in which a plurality of cells are connected in series is called a chain type cell connecting structure. For example, eight cells are connected in series. The number of cells may be, not eight, but sixteen, thirty-two, or more. Cells adjacent to one another share a diffusion layer. Further, a diffusion layer at one end of the chain is connected to a bit line 120 through a block selective transistor (not shown) which is turned on to select the chain. The other end of the chain is connected to a plate line (not shown). The gate electrode 30 of each cell is connected to a word line (not shown) extending in a direction perpendicular to the page.

Next, manufacturing processes of the ferroelectric memory according to the first embodiment of the present invention will be described with reference to cross-sectional views of FIGS. 2 and 3 in the direction of the bit line.

First, as shown in FIG. 2, an insulating film 20a, an electrode film 30a, a first interlayer insulating film 50a, a second interlayer insulating film 60a, and a ferroelectric film 80a are deposited on the substrate 10. Here, the ferroelectric film 80a may be crystallized by heat treatment. Further, as a ground film for prompting the crystallization of the ferroelectric film, a thin alumina film, a thin STO (SrTiO₃) film, a thin BSTO film, or the like may be deposited under the ferroelectric film.

Next, a mask film/protective film 130 is deposited over the surface of the ferroelectric film 80a. As the mask film/protective film 130, for example, a chemical vapor deposition (CVD) single layer film of a silicon oxide film may be used, or, for example, a CVD lamination layer film of a silicon nitride film and a silicon oxide film may be used. In FIG. 2, the mask film/protective film 130 is shown as a single layer for simplification. The mask film/protective film 130 is removed along the way of manufacturing the ferroelectric memory, and does not remain when the ferroelectric memory is completed. When a lamination layer film of a silicon oxide film and a silicon nitride film is used as the mask film/protective film 130, the silicon oxide film functions as a mask film in photolithography, and the silicon nitride film functions as, not only a mask film in photolithography, but also a protective film for protecting the ferroelectric film at the time of carrying out ion implantation into the silicon substrate 10 to form the diffusion layers 40.

Next, as shown in FIG. 3, a pattern 130a is formed by processing the mask film/protective film 130 by using photolithography and reactive ion etching (RIE).

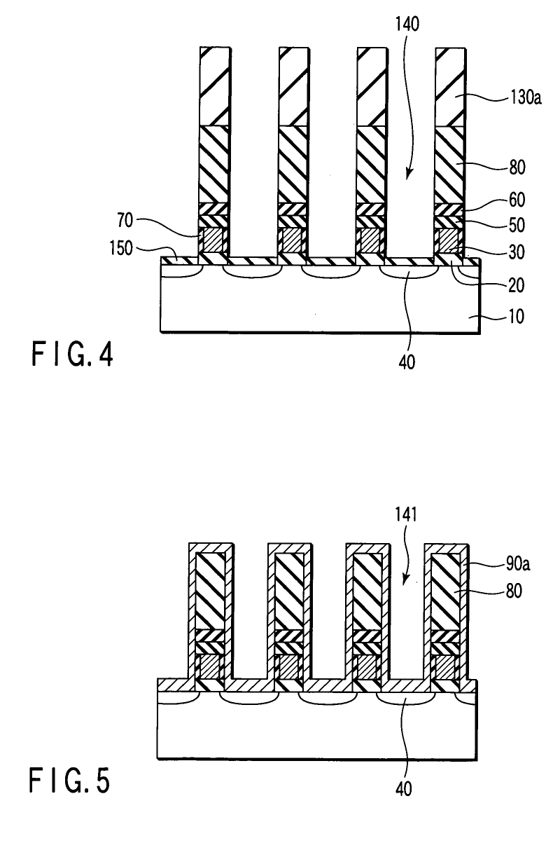

Then, selective etching is applied onto the ferroelectric film 80a, the second interlayer insulating film 60a, the first interlayer insulating film 50a, and the gate electrode film 30a by RIE with the pattern 130a being used as a mask, whereby grooves 140 are formed in the lamination layer of the ferroelectric film 80a, the second interlayer insulating film 60a, the first interlayer insulating film 50a, and the gate electrode film 30a, as shown in FIG. 4. Since the ferroelectric film 80a, the second interlayer insulating film 60a, the first interlayer insulating film 50a, and the gate electrode film 30a are etched in a self-aligning manner by this RIE, the side surfaces of these films are made the same plane.

Here, annealing is carried out with an aim to oxidize the side surfaces of the gate electrode and with an aim to eliminate the damage to the ferroelectric film. Crystallization of the ferroelectric film may be simultaneously carried out in the process of annealing. Annealing is carried out in the conditions that, for example, in the presence of oxygen at an annealing temperature of about 700° C. for about one hour. The sidewall insulating films 70 are formed at the side surfaces of the gate electrode by this annealing, and the side surfaces of the gate electrode are covered with the sidewall insulating films 70. Further, insulating films 150 composed of silicon oxide films are formed at the bottoms of the grooves 140 at the time of annealing. The silicon oxide films 150 are formed from portions of the gate insulating films 150 and oxide films on the surface layer of the substrate 10 formed by the above-described annealing. The thickness of the sidewall insulating films 70 is required to be made thick to the extent that a tunneling current is not made to flow into the sidewall insulating films 70 when a voltage difference of drive voltages is applied across the gate electrode and a wiring formed in a process later carried out. If the sidewall insulating films 70 are silicon oxide films, the thickness is preferably about 5 nm to about 20 nm. The projection of the sidewall insulating films 70 is a little in the structure in which the sidewall insulating films 70 have been formed. Therefore, the side surfaces of the gate electrode 30a including the ferroelectric film 80a, the second interlayer insulating film 60a, the first interlayer insulating film 50a, and the sidewall insulating films 70 are substantially the same plane.

Next, the diffusion layers 40 are formed in the substrate 10 by ion implantation, and thereafter, etching is carried out onto the insulting films 150 at the bottoms of the grooves 140 and the pattern 130a to be removed by using RIE.

Next, as shown in FIG. 5, a metal film is deposited over the surface of the substrate to form an electrode film 90a of a capacitor having a constant film thickness on the side surfaces of the grooves 140 and a metal film on the diffusion layers 40 of the substrate 10 at the bottoms in the grooves 141. The electrode film 90a is electrically connected to the diffusion layers 40 of the substrate 10 at the bottoms of the grooves 141. Namely, the diffusion layers 40 of the transistor and the side surfaces of the ferroelectric film 80 are connected through the same conductive layer. The film-forming method for the electrode film 90a is preferably a metal organic chemical vapor deposition (MOCVD) method capable of carrying out deposition at the side surfaces of the grooves and the bottoms of the grooves with satisfactory coating performance. However, the method may be in accordance with another method. The film thickness may be uneven. The gate electrodes of the plurality of cells on the same word line (not shown) extending in a perpendicular direction of the page are separated by photolithography and RIE.

Next, after the grooves 141 are completely filled by depositing third interlayer insulating films in the grooves 141, chemical mechanical polishing (CMP) for planarization is carried out.

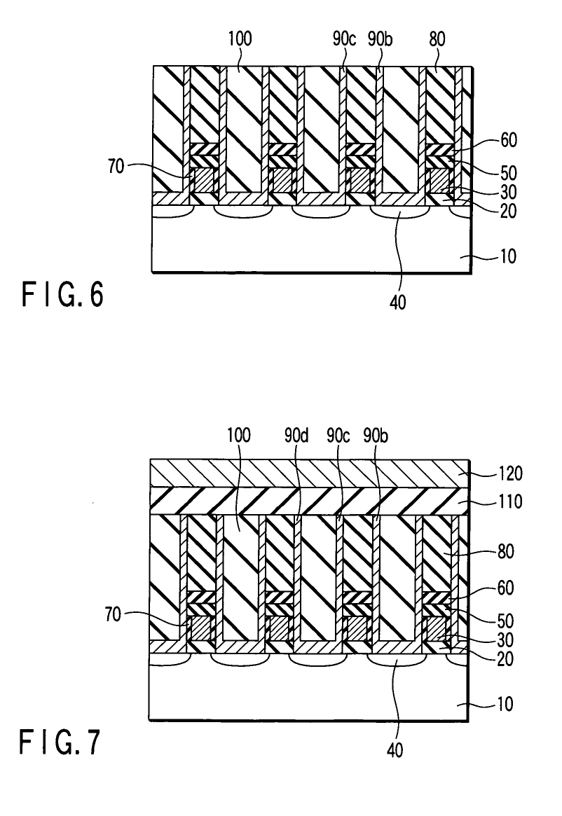

Subsequently, as shown in FIG. 6, the electrode film 90a is formed to be electrodes 90b and 90c by removing the portion of the electrode film 90a at the upper portion of the ferroelectric film 80 by CMP. Following this CMP process, a CMP process for planarization of the third interlayer insulating film 100 may be carried out.

Next, as shown in FIG. 7, a fourth interlayer insulating film 110 is deposited over the surface of the substrate, and next, the surface of the fourth interlayer insulating film 110 is processed so as to be flat by CMP. Moreover, a conductive film is deposited on the fourth interlayer insulating film 110, and next, the surface of the conductive film is planarized to form a bit line 120. Thereafter, the chain type ferroelectric memory device is completed through a process in which one end of the chain type cell connecting structure is connected to the bit line through a block selection transistor (not shown), and the opposite end of the chain is connected to a plate line (not shown).

In accordance with the above first embodiment, unlike in a conventional manufacturing method, there is no need to respectively form a contact hole of a transistor and electrodes of a capacitor by photolithography separately. Namely, the transistor and the ferroelectric capacitor are formed in a self-aligning manner, and extra space for covering misalignment among a contact hole of the transistor and the ferroelectric capacitor is not required, which results in obtaining the miniaturization of the ferroelectric memory device.

Further, in accordance with the present embodiment, the electrodes 90c and 90d is in contact with the diffusion layers 40 of the transistor, and the ferroelectric films 80 of the cells adjacent to one another, so that it is easy to form the capacitor electrodes and the contact portions.

### Second Embodiment

In the first embodiment, the electrodes 90 and 91 of the capacitor are formed from deposited layers obtained by depositing a conductive material on the side surfaces of the ferroelectric film so as to have a constant film thickness. In the present embodiment, however, the electrodes of the capacitors and the contacts to the diffusion layers of the transistor are formed from buried layers of a conductive material.

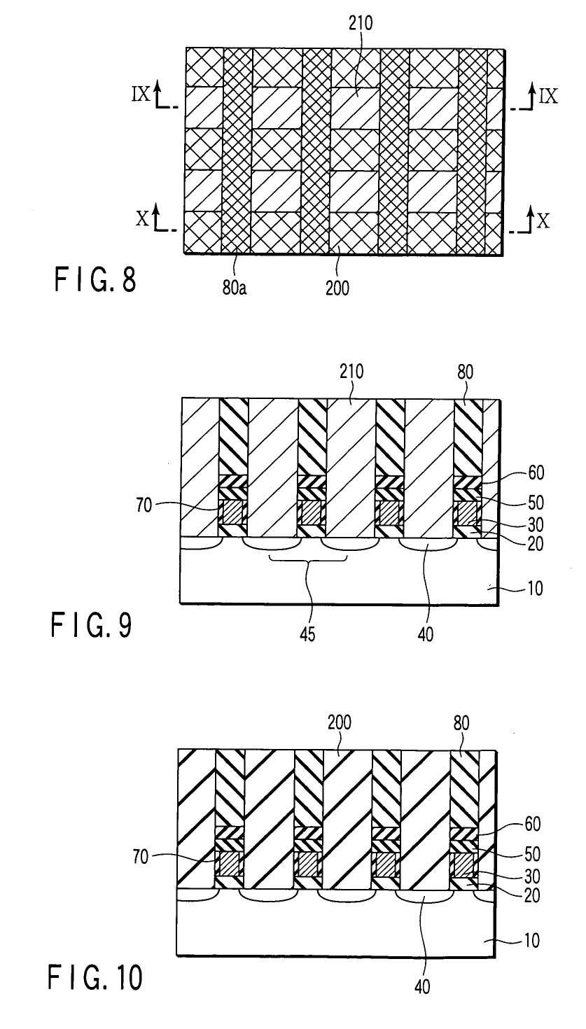

FIG. 8 is a plan view of the ferroelectric memory device of this embodiment, and FIGS. 9 and 10 are cross-sectional views thereof. Portions corresponding to those in the first embodiment are denoted by the same reference numerals, and detailed descriptions thereof will be omitted.

FIG. 9 is the cross-sectional view of the ferroelectric memory device taken along the line IX-IX of FIG. 8, and FIG. 10 is the cross-sectional view of the ferroelectric memory device taken along the line X-X of FIG. 8.

An electrode material 210 is embedded in a plurality of electrode regions, and a fifth interlayer insulation film 200 is embedded in a plurality of isolation regions.

The second embodiment is different from the first embodiment in that, as shown in FIG. 9, electrodes 210 are embedded between the elements adjacent to each other on the cross-section along the line IX-IX of FIG. 8, and that, as shown in FIG. 10, the fifth interlayer insulating film 200 is embedded between the elements adjacent to each other on the cross-section along the line X-X of FIG. 8.

The other structures are the same as in the first embodiment. The second embodiment is the same as in the first embodiment in that, as shown in FIG. 9, the transistor 45 including the gate insulating film 20, the gate electrode 30, the sidewall insulating films 70 of the gate electrode, and the diffusion layers 40 is provided on the substrate 10, and that the ferroelectric film 80 is provided through the first interlayer insulating film 50 and the second interlayer insulating film 60 on the gate electrode 30 and the bit line 120 (FIG. 1) is provided through the fourth interlayer insulating film 110 (FIG. 1) on the ferroelectric film 80.

Further, the second embodiment is also the same as in the first embodiment in that a chain type cell connecting structure in which eight cells are connected in series is provided, the diffusion layer at one end of the chain is connected to the bit line 120 through a block selective transistor (not shown), the other end of the chain is connected to a plate line (not shown), and further, the cells are connected to a word line (not shown) extending in a direction perpendicular to the page through the gate electrodes.

Next, a manufacturing process for the ferroelectric memory according to the second embodiment will be described with reference to the cross-sectional views of FIGS. 9 and 10.

First, processes which are the same as those described in the first embodiment with reference to FIGS. 2, 3 and 4 are carried out. Namely, the processes in which the transistor portions and the ferroelectric film portions are formed, and further, the diffusion layers are formed are carried out. Thereafter, in the second embodiment, the electric material 210 are embedded between the ferroelectric films 80, as shown in FIG. 9. For example, Pt is used as the electric material 210, and after deposition of Pt is carried out by using, for example, the MOCVD method, the deposited Pt layer is planarized by CMP. Subsequently, the electrode material 210 in the isolation regions are removed by using photolithography and RIE, and the grooves formed by this removal are embedded with the fifth interlayer insulating film 200 such as a silicon oxide film as shown in FIG. 10. Thereafter, in the same way as described with reference to FIG. 7 in the first embodiment, the electrode portions formed on the ferroelectric films 80 are removed by CMP, the fourth interlayer insulating film 110 (FIG. 7) is deposited over the surface of the substrate, the surface of the fourth interlayer insulating film 110 is processed to be flat by CMP, and moreover, a conductive material is deposited over the fourth interlayer insulating film 110 and the surface of the conductive material is planarized to form the bit line 120. Moreover, the chain type ferroelectric memory device is completed through a process in which one end of the chain type cell connecting structure is connected to the bit line 120 through a block selective transistor (not shown), and the opposite end of the chain is connected to a plate line (not shown).

In the present embodiment as well, similar effects to those of the first embodiment can be obtained. Moreover, an attempt can be made to reduce the number of processes by embedding the capacitor electrode material. When the memory cells are miniaturized, and the gates of the cell transistors adjacent to one another are close to one another, the number of processes as in the present embodiment in which the gates are embedded with the electrode material, or the ferroelectric materials of the capacitor are embedded with the conductive material is less than the number of processes in the first embodiment.

### Third Embodiment

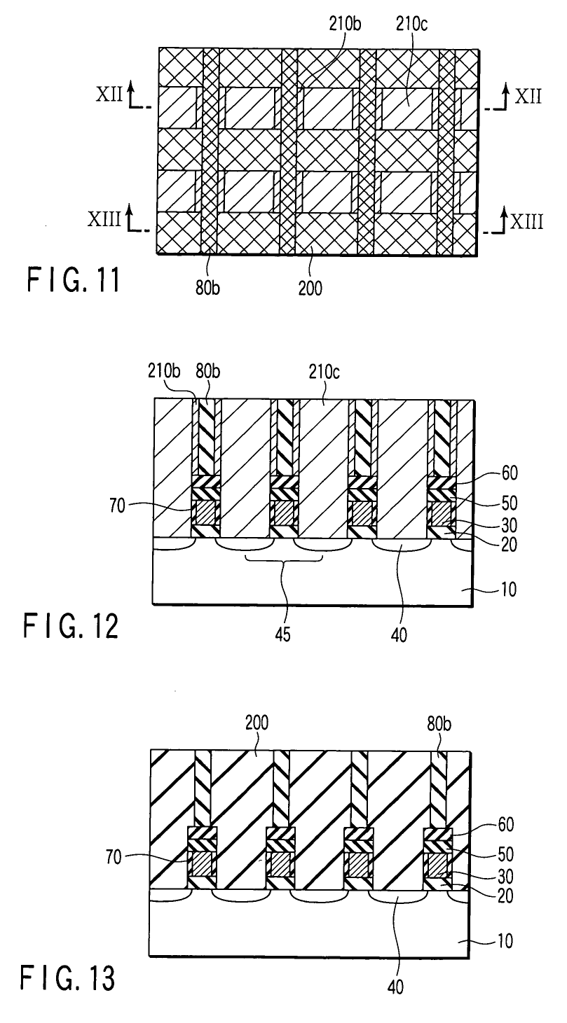

FIG. 11 is a plan view of a ferroelectric memory device according to a third embodiment of the present invention, and FIGS. 12 and 13 are cross-sectional views thereof. FIG. 12 is the cross-sectional view of the ferroelectric memory device taken along the line XII-XII of FIG. 11, and FIG. 13 is the cross-sectional view of the ferroelectric memory device taken along the line XIII-XIII of FIG. 11.

In FIG. 11, the fifth interlayer insulating film 200 is embedded in a plurality of element regions. At the plurality of electrode regions, first electrodes 210b are formed so as to have a constant film thickness at the side surfaces of the ferroelectric films 80b, and second electrodes 210c are embedded in the grooves between the ferroelectric films 80b. Namely, the first electrodes 210b are provided at both sides of the second electrodes 210c at the plurality of electrode regions.

As shown in FIG. 12, the length of the ferroelectric film 80b in a direction along the channel length of the transistor 45 is shorter than the channel length of the transistor 45. Moreover, the first electrode material 210b is deposited on the side surfaces of the ferroelectric film 80b, and the second electrode material 210c is embedded between the elements adjacent to one another. In FIG. 13 as well, the length of the ferroelectric film 80b in a direction along the channel length of the transistor 45 is shorter than the channel length of the transistor 45, and the fifth interlayer insulating film 200 is embedded between the elements adjacent to one another.

The other structures are the same as those in the first embodiment. As shown in FIG. 12, the transistor 45 which includes the gate insulating film 20, the gate electrode 30, the sidewall insulating films 70 of the gate electrode, and the diffusion layers 40 is provided on the substrate 10. The third embodiment is the same as in the first embodiment in that the ferroelectric film 80 is formed through the first interlayer insulating film 50 and the second interlayer insulating film 60 on the gate electrode 30, and that the bit line 120 (FIG. 1) is formed through the fourth interlayer insulating film 110 (FIG. 1) on the ferroelectric film 80.

Further, the third embodiment is the same as in the first embodiment in that a chain type cell connecting structure in which eight cells are connected in series is provided, the diffusion layer at one end of the chain is connected to the bit line 120 through a block selective transistor (not shown), the other end of the chain is connected to a plate line (not shown), and the cells are connected to a word line (not shown) extending in a direction perpendicular to the page through the gate electrode.

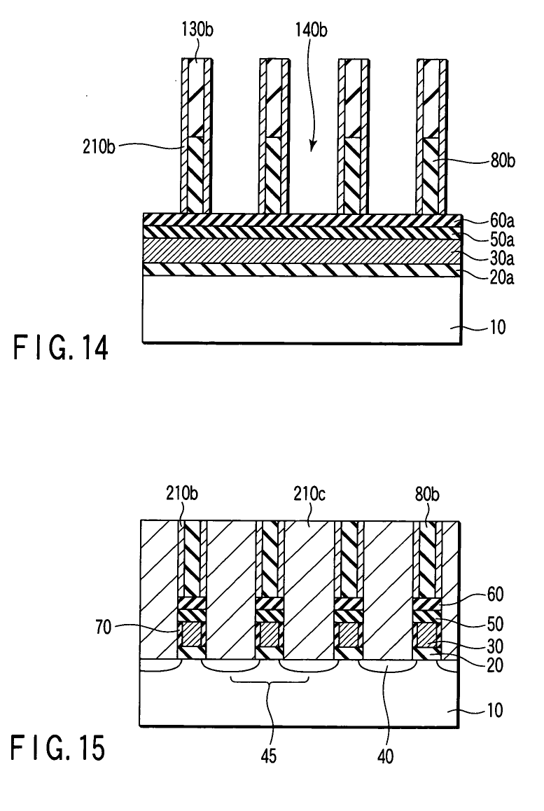

FIGS. 14 and 15 are cross-sectional views of a device structure for explanation of a method of manufacturing the ferroelectric memory device according to the third embodiment of the present invention.

First, processes which are the same as those described in the first embodiment with reference to FIGS. 2 and 3 are carried out. Namely, the processes until a pattern is formed on the ferroelectric film are carried out. Thereafter, in the third embodiment, grooves 140b are formed by etching the ferroelectric film 80b by RIE with the pattern 130b being used as a mask, as shown in FIG. 14. Next, a first electrode material is deposited so as to be embedded in the grooves 140b, and then, the deposited first electrode material is planarized by CMP. Next, etching is carried out to the first electrode material layer by using photolithography and RIE, and as shown in FIG. 14, the first electrode films 210b are formed at the side surfaces of the ferroelectric film 80b. At that time, the first electrode films 210b are formed also at the side surfaces of the pattern 130b, which does not become something of a problem.

Subsequently, the second interlayer insulating film 60a, the first interlayer insulating film 50a, and the gate electrode 30a are processed by using RIE with the pattern 130b and the first electrodes 210b being as a mask. The second interlayer insulating film 60a, the first interlayer insulating film 50a, and the gate electrode 30a are formed in a self-aligning manner by this RIE by using the pattern 130b and the first electrodes 210b as a mask. Consequently, those sidewalls are made to be the same plane.

Then, annealing is carried out with an aim to oxidize the side surfaces of the gate electrode and to restore the damage to the ferroelectric film. Annealing is carried out in the conditions that, for example, in the presence of oxygen at an annealing temperature of about 700° C. for about one hour. The sidewalls of the gate electrode are oxidized by this annealing, the sidewall insulating films 70 are formed at the side surfaces of the gate electrode as shown in FIG. 15, and the side surfaces of the gate electrode are covered with the sidewall insulating films 70. The projection of the sidewall insulating films 70 is a little in the structure in which the sidewall insulating films 70 have been formed. Therefore, the side surfaces of the gate electrode 30a including the ferroelectric film 80a, the second interlayer insulating film 60a, the first interlayer insulating film 50a, and the sidewall insulating films 70 are substantially the same plane.

Next, the diffusion layers 40 are formed in the substrate 10 by ion implantation, and thereafter, etching is carried out on the silicon oxide film over the entire surface by using RIE. By this etching, the pattern 130b and the insulating films at the bottoms of the grooves 140b are also removed.

Thereafter, in the present embodiment, the grooves 140b are embedded with the second electric material 210c, as shown in FIG. 15. As the second electric material 210c, the same material as that of the first electrode 210b may be used, or another material with a sufficient affinity to the CMOS process, such as tungsten, may be used.

Then, in the present embodiment, grooves are formed by removing the first electrode material 210b and the second electrode material 210c at the isolation regions (not shown) by using photolithography and RIE in the same way as in the second embodiment. For this etching, it is preferable that the etching conditions are set such that the second electrode material 210c and the first electrode material 210b can be simultaneously etched. For example, it is preferable to set such conditions under which by using a chlorine-based etching agent, the etching selectivity between the first electrode material 210b and the second electrode material 210c is close to 1, and an etching rate of the gate electrode film is extremely smaller than the selectivity. When different etching conditions are set for the first electrode material 210b and the second electrode material 210c, for example, a lamination layer film of titanium and titanium nitride may be deposited in advance at the bottoms of the grooves 140b in order to avoid the damage to the bottoms of the grooves 140b due to excess etching onto the bottoms of the grooves 140b. This lamination layer film of titanium and titanium nitride can be also removed by a chlorine-based etching agent.

Following this process, the grooves formed by removing the electrode material are embedded with the fifth interlayer insulating film material 200 (FIG. 10) such as a silicon oxide film, and then, the embedded interlayer insulating film 200 is planarized by CMP or the like, and at the same time, the interlayer insulating film 200 at the upper portion of the ferroelectric film is removed. Thereafter, the ferroelectric memory device is completed through the processes for connecting to the bit line, the word line, and the plate line, and the like.

In the present embodiment as well, similar advantages to those of the first embodiment can also be obtained. Moreover, in the first and second embodiments, a distance between the electrodes of the ferroelectric film 80 is formed so as to be substantially equal to the channel length of a transistor. On the other hand, in the present embodiment, the processes are made complicated, however, a distance between the electrodes of the ferroelectric film 80 can be set separately from the channel length of a transistor, and it is possible to optimize the film thickness of the capacitor of the ferroelectric film 80 in accordance with an operating voltage of the storage device. Further, in the point that the electrode material of the capacitor and the contact material of the diffusion layers can be separately selected, there is an advantage over the first and second embodiments.

Note that the present invention is not limited to the above structures, and various modifications are possible. For example, as a material of the electrodes, a metal material such as Ir and Ru may be used, and those may be made of conductive oxide such as IrO₂ and RuO₂. In the respective embodiments, the chain type ferroelectric memory devices have been described. However, the present invention can be applied to a conventional ferroelectric memory device which is not a chain type. Further, the present invention can be applied, in cases of both of the chain type and the conventional type, to a ferroelectric memory device having any of the 1-transistor/1-capacitor (1T1C) structure, the 2-transistor/2-capacitor (2T2C) structure (a system described in ISSCC 1998 p130 and the like), and the 1-transistor/2-capacitor (1T2C) structure.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A ferroelectric memory device comprising:
an MIS transistor formed on a substrate;
a ferroelectric film which is formed above the MIS transistor through an interlayer insulating film, and which has a width substantially equal to a channel length of the MIS transistor; and
a same wiring layer which connects a diffusion layer of the MIS transistor formed in a surface region of the substrate to a side surface of the ferroelectric film.

2. The ferroelectric memory device according to claim 1, wherein the ferroelectric memory device is a ferroelectric memory device of a chain type structure in which a plurality of cells are connected in series and share one bit line.

3. The ferroelectric memory device according to claim 1, wherein the side surface of the ferroelectric film and a side surface of the MIS transistor including a sidewall insulating film of a gate electrode are substantially in the same plane.

4. The ferroelectric memory device according to claim 1, wherein the wiring layer is composed of a wiring film having a predetermined thickness.

5. The ferroelectric memory device according to claim 1, wherein the wiring layer is composed of a wiring layer embedded between two cells adjacent to each other.

6. A ferroelectric memory device comprising:
an MIS transistor formed on a substrate;
a ferroelectric film which is formed above the MIS transistor through an interlayer insulating film, and which has a width shorter than a channel length of the MIS transistor;
a wiring film of a predetermined thickness formed on a side surface of the ferroelectric film; and
a wiring layer which is embedded between two cells adjacent to each other, and which connects a diffusion layer of the MIS transistor formed in a surface region of the substrate to the ferroelectric film through the wiring film.

7. The ferroelectric memory device according to claim 6, wherein the ferroelectric memory device is a ferroelectric memory device of a chain type structure in which a plurality of cells are connected in series and share one bit line.

8. The ferroelectric memory device according to claim 6, wherein a side surface of the wiring film and a side surface of the MIS transistor including a sidewall insulating film of a gate electrode are substantially in the same plane.

9. The ferroelectric memory device according to claim 6, wherein the wiring film and the wiring layer are made of the same material.

10. The ferroelectric memory device according to claim 6, wherein the wiring film and the wiring layer are made of different materials.

11. A ferroelectric memory device comprising:
an MIS transistor formed on a substrate;
a ferroelectric capacitor which is formed from a ferroelectric film and a pair of electrodes through an interlayer insulating film above the MIS transistor, said pair of electrodes being arranged in a direction of a channel length of the MIS transistor; and
a same wiring layer which connects a diffusion layer of the MIS transistor formed in a surface region of the substrate to a corresponding one of the electrodes of the ferroelectric capacitor.

12. The ferroelectric memory device according to claim 11, wherein the ferroelectric memory device is a ferroelectric memory device of a chain type structure in which a plurality of cells are connected in series and share one bit line.

13. The ferroelectric memory device according to claim 11, wherein a side surface of the ferroelectric film and a side surface of the MIS transistor including sidewall insulating films of a gate electrode are substantially in the same plane.

14. The ferroelectric memory device according to claim 11, wherein the wiring layer is composed of a wiring film having a predetermined thickness.

15. The ferroelectric memory device according to claim 11, wherein the wiring layer is composed of a wiring layer embedded between two cells adjacent to each other.

16. A ferroelectric memory device comprising:
an MIS transistor formed on a substrate;
a ferroelectric capacitor which is formed from a ferroelectric film and a pair of electrodes through an interlayer insulating film above the MIS transistor, said pair of electrodes being arranged in a direction of a channel length of the MIS transistor;
a wiring film of a predetermined thickness formed on a side surface of the ferroelectric film; and
a wiring layer which is embedded between two cells adjacent to each other, and which connects a diffusion layer of the MIS transistor formed in a surface region of the substrate to the ferroelectric film through the wiring film.

17. The ferroelectric memory device according to claim 16, wherein the ferroelectric memory device is a ferroelectric memory device of a chain type structure in which a plurality of cells are connected in series and share one bit line.

18. The ferroelectric memory device according to claim 16, wherein side surfaces of the wiring film and side surfaces of the MIS transistor including sidewall insulating films of a gate electrode are substantially in the same plane.

19. A method of manufacturing a ferroelectric memory device, comprising:
forming an insulating film on a surface of a substrate;
depositing a gate electrode film on the insulating film;
depositing an interlayer insulating film on the gate electrode;
depositing a ferroelectric film on the interlayer insulating film;
processing the ferroelectric film, the interlayer insulating film, the gate electrode film, and the insulating film mutually in a self-aligning manner;
forming diffusion layers in the substrate; and
forming a same wiring film which connects the ferroelectric film and the diffusion layers.

20. A method of manufacturing a ferroelectric memory device, comprising:
forming an insulating film on a principal surface of a substrate;
depositing a gate electrode film on the insulating film;
depositing an interlayer insulating film on the gate electrode;
depositing a ferroelectric film on the interlayer insulating film;
processing the ferroelectric film;
forming capacitor electrode films on side surfaces of the processed ferroelectric film;
processing the interlayer insulating film, the gate electrode film, and the insulating film mutually with the capacitor electrode films in a self-aligning manner;
forming diffusion layers in the substrate; and
forming a buried wiring layer which connects the ferroelectric film and the diffusion layers.
